(19) United States
(12) Patent Application Publication
(10) Pub. No.: US 2007/0227762 A1
(43) Pub. Date: Oct. 4, 2007

(54) Multilayer circuit board with grounding grids and method for controlling characteristic impedance of the multilayer circuit board

(75) Inventors: Wilson Yang, Taoyuan Hsien (TW); Chih-Chien Lin, Taoyuan Hsien (TW); Yen-Jui Chen, Taoyuan Hsien (TW)

Correspondence Address: BIRCH STEWART KOLASCH & BIRCH, PO BOX 747, FALLS CHURCH, VA, 22040-0747, US

(73) Assignee: COMPEQ MANUFACTURING COMPANY LIMITED

(21) Appl. No.: 11/396,630

(22) Filed: Apr. 4, 2006

(51) Int. Cl. H05K 1/03

(52) U.S. Cl. 174/255

(57) ABSTRACT

A multilayer circuit board has a first insulating layer, a first grounding grid layer and a transmission layer. The first grounding grid layer is formed below the bottom surface of the first insulating layer and has multiple grids. The grids are arranged in an array pattern and are made of metal, and each grid has a centerline and a shape. Centerlines of adjacent grids are separated by a first distance. The transmission layer is formed on the top surface of the first insulating layer and has at least one transmission line and a datum line. The datum line corresponds to the centerline of one of the grids and is separated from the transmission line by a second distance. The second distance can be quarters of the first distance. Since the characteristic impedance is controlled by varying the second distance, different second distance results in different characteristic impedance.

### BACKGROUND OF THE INVENTION

1. Field of the Invention

The present invention relates to a multilayer circuit board and a method, and more particularly to a multilayer circuit board with grounding grids and a method for controlling characteristic impedance of the multilayer circuit board.

2. Description of Related Art

A multilayer circuit board in accordance with the prior art has inductance (L), capacitance (C) and characteristic impedance (Zo) and comprises a flexible insulating substrate, multiple signal conductors and a grounding layer. The substrate has a top surface and a bottom surface. The signal conductors are mounted on the top surface of the substrate. The grounding layer is made of metal and is formed below the bottom surface of the substrate. However, the grounding layer decreases the flexibility of the multilayer circuit board. The characteristic impedance (Zo) of the multilayer circuit board relates to inductance (L) and capacitance (C) per unit length of the multilayer circuit board relative to the grounding layer. A formula to calculate characteristic impedance (Zo) of the multilayer circuit board is Zo=\sqrt{L/C}.

To overcome the shortcomings, the grounding grid replaces the grounding layer. For example, a flexible printed circuit in U.S. Pat. No. 6,559,377 includes an elongated flexible insulating substrate with multiple signal conductors extending longitudinally along one side of the substrate. A grounding grid having a substantially random geometric pattern is formed on the opposite side of the substrate. The patent also discloses improved impedance characteristics.

However, the grounding grid with a random geometric pattern is difficult to design, and how to control the characteristic impedance of the multilayer circuit board is not mentioned in the prior art.

To overcome the shortcomings, the present invention provides a multilayer circuit board with grounding grids and a method for controlling characteristic impedance of the multilayer circuit board to mitigate or obviate the aforementioned problems.

### SUMMARY OF THE INVENTION

The main objective of the invention is to provide a multilayer circuit board with grounding grids and a method for controlling characteristic impedance of the multilayer circuit board.

A multilayer circuit board in accordance with the present invention has a controllable characteristic impedance and comprises a first insulating layer, a first grounding grid layer and a transmission layer. The first insulating layer has a bottom surface and a top surface. The first grounding grid layer is formed below the bottom surface of the first insulating layer and has multiple grids. The grids are arranged in an array pattern and are made of metal, and each grid has a centerline and a shape. The centerlines of adjacent grids are separated by a first distance. The shapes of the grids are the same and are symmetrical. The transmission layer is formed on the top surface of the first insulating layer and has at least one transmission line and a datum line. The datum line corresponds to the centerline of one of the grids and is separated from the transmission line by a second distance. The second distance can be quarters of the first distance. Since the characteristic impedance is controlled by varying the second distance, different second distance results in different characteristic impedance.

Other objectives, advantages and novel features of the invention will become more apparent from the following detailed description when taken in conjunction with the accompanying drawings.

### BRIEF DESCRIPTION OF THE DRAWINGS

FIG. 1 is a top view of a first embodiment of a multilayer circuit board in accordance with the present invention with diamond-shaped grids;

FIG. 2 is a front view in partial section of the multilayer circuit board in FIG. 1;

FIG. 3 is a front view in partial section of a second embodiment of a multilayer circuit board in accordance with the present invention with a second insulating layer and a second grounding grid layer;

FIG. 4 is a graph of inductance per unit length of the multilayer circuit board in FIG. 1 with different second distances;

FIG. 5 is a graph of capacitance per unit length of the multilayer circuit board in FIG. 1 with different second distances;

FIG. 6 is a graph of characteristic impedance of the multilayer circuit board in FIG. 1 with different second distances;

FIG. 7 is a top view of a third embodiment of a multilayer circuit board in accordance with the present invention with circular grids; and

FIG. 8 is a graph of characteristic impedance of the multilayer circuit board in FIG. 7 with different second distances.

### DETAILED DESCRIPTION OF PREFERRED EMBODIMENT

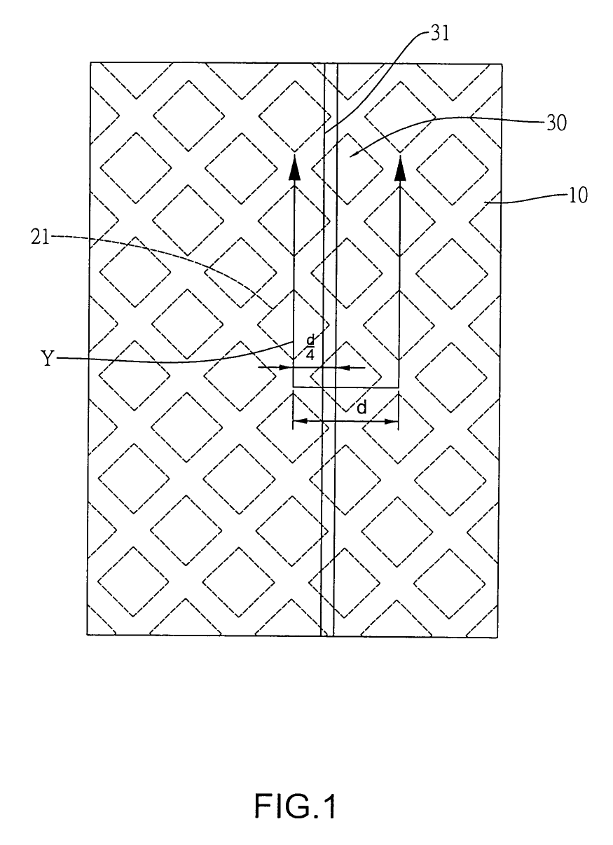

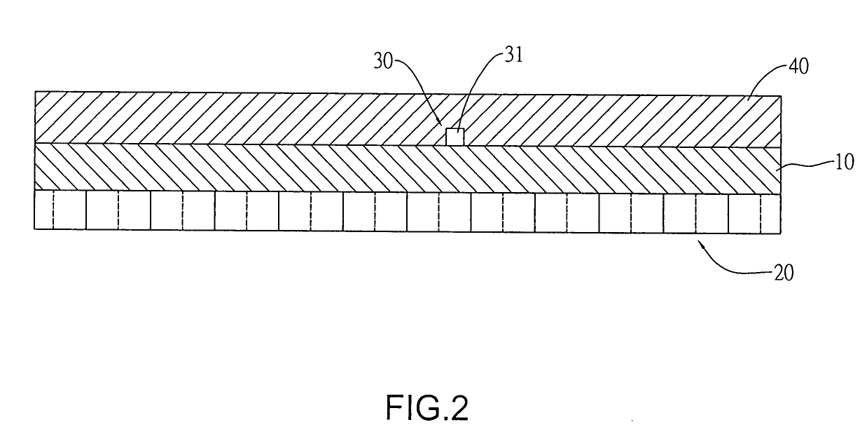

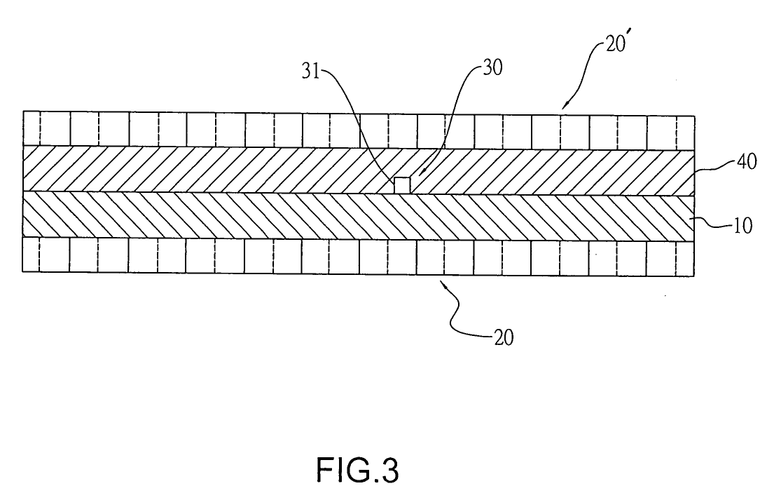

With reference to FIGS. 1 to 3, a multilayer circuit board with grounding grids in accordance with the present invention comprises a first insulating layer (10), a first grounding grid layer (20), a transmission layer (30), an optional second insulating layer (40) and an optional second grounding grid layer (20′).

The first insulating layer (10) has a bottom surface and a top surface.

The first grounding grid layer (20) is formed below the bottom surface of the first insulating layer (10) and has multiple grids (21).

The grids (21) are arranged in an array pattern and are metal, and each grid (21) has a centerline and a shape. Centerlines of adjacent grids (21) are separated by a first distance (d).

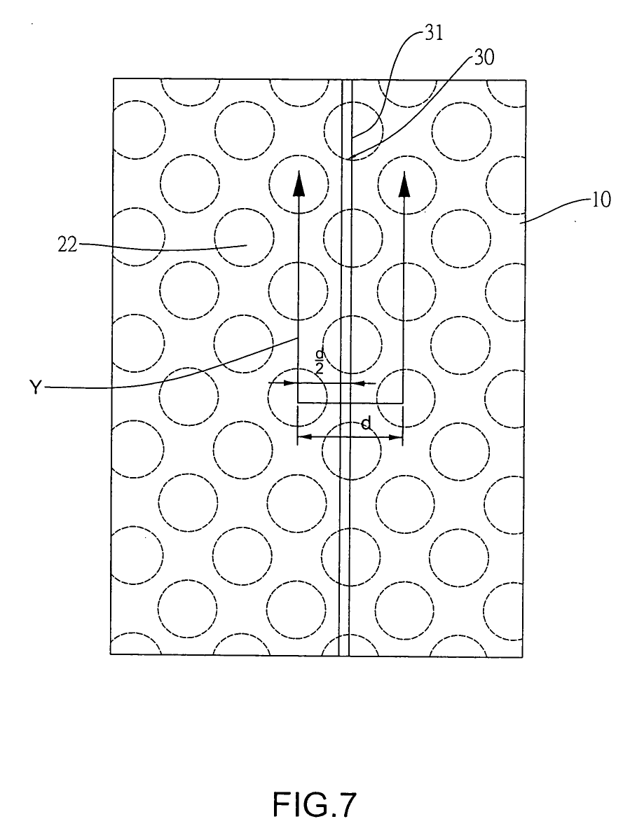

With further reference to FIG. 7, the shapes of the grids (21) are the same, are symmetrical and can be diamonds, polygons, circles, ellipses or the like.

The transmission layer (30) is formed on the top surface of the first insulating layer (10) and has at least one transmission line (31) and a datum line (Y).

The transmission line (31) is formed on the top surface of the first insulating layer (10) and is parallel to the centerlines of the grids (21).

The datum line (Y) corresponds to the centerline of one of the grids (21) and is separated from the transmission line (31) by a second distance. The second distance can be quarters of the first distance (d).

The second insulating layer (40) is formed on the top surface of the first insulating layer (10), encloses the transmission line (31) and has a top surface.

The second grounding grid layer (20′) has multiple grids (21) formed on the top surface of the second insulating layer (40).

The method for controlling the characteristic impedance of the multilayer circuit board comprises acts of (1) forming at least one grounding grid layer (20) and the transmission layer (30) in the multilayer circuit board and (2) installing a transmission line (31) at a specific second distance from a datum line (Y) to control characteristic impedance of the multilayer circuit board.

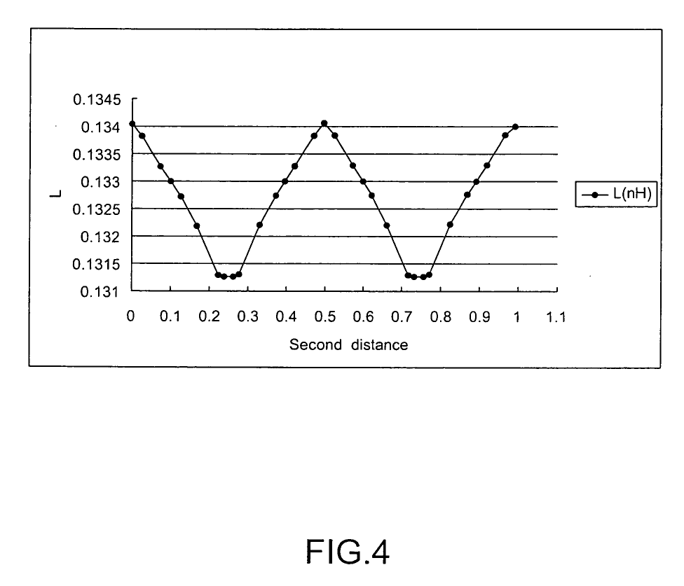

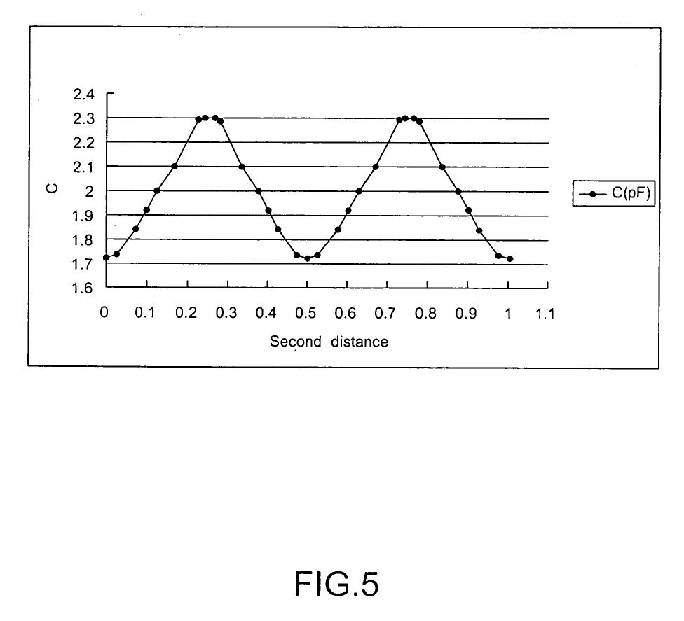

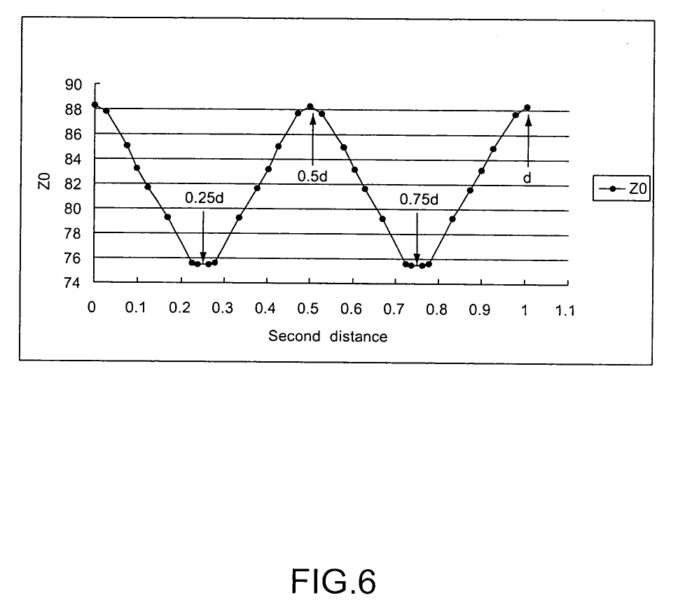

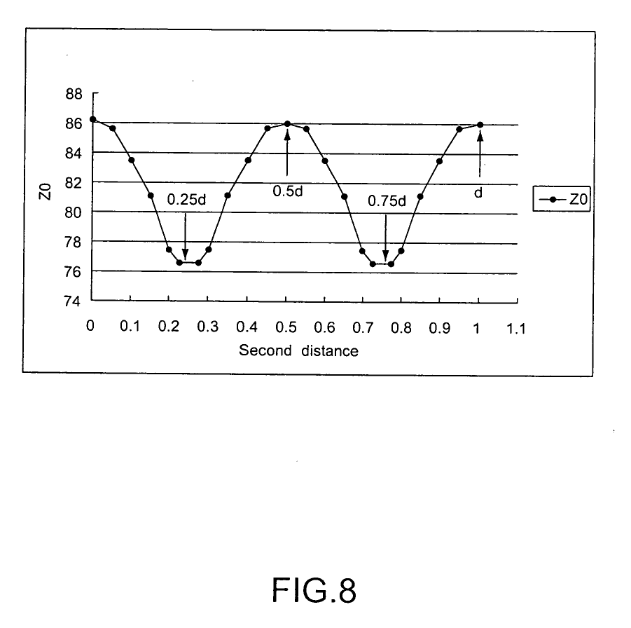

From the formula Zo=\sqrt{L/C}, the characteristic impedance (Zo) of the multilayer circuit board is obtained by inductance (L) and capacitance (C) per unit length of the multilayer circuit board. With further reference to FIGS. 4 and 5, the inductance (L) per unit length of the multilayer circuit board is a minimum and a maximum level when the second distance is a multiple of a quarter of the first distance (d) and is inversely related to the capacitance (C) per unit length of the multilayer circuit board. With further reference to FIGS. 6 and 8, the characteristic impedance of the multilayer circuit board is a minimum and a maximum level when the second distance is a multiple of a quarter of the first distance (d).

With such a multilayer circuit board, the characteristic impedance (Zo) of the multilayer circuit board is controlled by the second distance. Thus, a different characteristic impedance (Zo) is implemented with a corresponding second distance. The symmetrical shapes of grids replace conventional grids having random geometric pattern and simplify design.

Even though numerous characteristics and advantages of the present invention have been set forth in the foregoing description, together with details of the structure, function and method of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A multilayer circuit board with grounding grids comprising:
a first insulating layer having a bottom surface and a top surface;
a first grounding grid layer formed below the bottom surface of the first insulating layer and having multiple grids arranged in an array pattern and made of metal, and each grid having
a centerline being separated from centerlines of adjacent grids by a first distance; and
a shape being the same as the shapes of the other grids and being symmetrical; and
a transmission layer formed on the top surface of the first insulating layer and having
at least one transmission line formed on the top surface of the first insulating layer and being parallel to the centerlines of the grids; and
a datum line corresponding to the centerline of one of the grids and separated from the transmission line by a second distance.

2. The multilayer circuit board as claimed in claim 1, wherein the shapes of grids are diamonds.

3. The multilayer circuit board as claimed in claim 1, wherein the shapes of grids are circles.

4. The multilayer circuit board as claimed in claim 1, wherein the second distance is an even multiple of a quarter of the first distance.

5. The multilayer circuit board as claimed in claim 1, wherein the second distance is an odd multiple of a quarter of the first distance.

6. The multilayer circuit board as claimed in claim 1 further comprising a second insulating layer formed on the top surface of the first insulating layer, enclosing the transmission line and having a top surface.

7. The multilayer circuit board as claimed in claim 6 further comprising a second grounding grid layer formed with multiple grids on the top surface of the second insulating layer.

8. A method for controlling characteristic impedance of a multilayer circuit board with grounding grids comprising acts of:
forming at least one grounding grid layer and a transmission layer in a multilayer circuit board, wherein
the grounding grid layer has
multiple grids arranged in an array pattern and made of metal, and each grid having
a centerline being separated from centerlines of adjacent grids by a first distance; and
a shape being the same as shapes of the other grids and being symmetrical; and
the transmission layer has
at least one transmission line formed in the multilayer circuit board and being parallel to the centerlines of the grids; and
a datum line corresponding to the centerline of one of the grids and separated from the transmission line by a second distance; and
installing the transmission line at a specific second distance from the datum line to control characteristic impedance of the multilayer circuit board.

9. The method as claimed in claim 8, wherein the shapes of grids are diamonds.

10. The method as claimed in claim 8, wherein the shapes of grids are circles.

11. The method as claimed in claim 8, wherein the second distance is an even multiple of a quarter of the first distance.

12. The method as claimed in claim 8, wherein the second distance is an odd multiple of a quarter of the first distance.
